(19) United States
(12) Patent Application Publication
(10) Pub. No.: US 2008/0303103 A1
(43) Pub. Date: Dec. 11, 2008

(54) SEMICONDUCTOR STRUCTURE AND METHOD OF FORMING THE SAME

(75) Inventors: Kuo Chung CHEN, Taipei (TW); Jen-Jui HUANG, Taipei (TW); Hong Wen LEE, Taipei (TW)

Correspondence Address: INGRASSIA FISHER & LORENZ, P.C., 7010 E. COCHISE ROAD, SCOTTSDALE, AZ, 85253, US

(73) Assignee: NANYA TECHNOLOGY CORP., Taoyuan (TW)

(21) Appl. No.: 11/932,620

(22) Filed: Oct. 31, 2007

(30) Foreign Application Priority Data
Jun. 5, 2007 (TW) 96120101

(51) Int. Cl. H01L 29/78; H01L 21/336

(52) U.S. Cl. 257/408; 438/302; 257/E29.266; 257/E21.437

(57) ABSTRACT

The present invention provides a semiconductor structure and a method of forming the same. The method includes the steps of providing a substrate, forming a mask layer with an opening on the substrate, locally oxidizing the substrate to form an oxide layer within the opening, removing the oxide layer, such that a partial surface of the substrate becomes a curve surface, forming a sacrificial layer on the curve surface, forming a first doped region in the substrate and under the hard mask layer, forming a gate stack within the opening, removing the hard mask layer, forming a spacer on a sidewall of the gate stack, and forming a second doped region in the substrate and under the spacer. The second doped region has a dopant concentration is larger than that of the first doped region. Therefore, the oxide layer increases the surface area of the substrate so as to increase the channel length. Thus, the leakage between the source region and the drain region can be improved.

### RELATED APPLICATION

This application claims the right of priority based on Taiwan Patent Application No. 096120101 entitled “A SEMICONDUCTOR STRUCTURE AND THE FORMING METHOD THEREOF”, filed on Jun. 5, 2007, which is incorporated herein by reference and assigned to the assignee herein.

### FIELD OF INVENTION

The present invention generally relates to a semiconductor structure, and more particularly, to a method of forming an oxide layer on the substrate by using a local oxidation of silicon process, so as to increase the surface distance of the substrate and the channel length between the source region and the drain region.

### BACKGROUND OF THE INVENTION

Among the semiconductor devices, metal-oxide semiconductor field-effect transistor (MOSFET) is one of the most important devices of the very-large-scale integrated (VLSI) circuit. A MOSFET generally includes a gate structure on a gate dielectric layer, a source region, and a drain region. The source region and the drain region are at opposite sides with respect to the gate structure and separated by a channel.

The thickness of the gate dielectric layer has to be minimized to increase the source/drain current (S/D current). However, the effective oxide thickness (EOT) of a silicon dioxide or a silicon nitride is relatively small, which causes a tunneling effect and increases the current leakage. Furthermore, if the channel length between the source region and the drain region is too short, the current leakage will affect the operation of MOS device.

### SUMMARY OF THE INVENTION

One object of the present invention is to provide a method of forming an oxide layer on a partial surface of the substrate by a local oxidation of silicon process, and thereby to increase the surface distance of the substrate and the channel length.

In one embodiment, the present invention provides a semiconductor structure and a method thereof. The method includes providing a substrate; forming a hard mask layer with an opening on the substrate; forming an oxide layer within the opening; removing the oxide layer such that a partial surface of the substrate becomes a curve surface to increase the channel length; forming a sacrificial layer on the curve surface; forming a first doped region in the substrate and under the hard mask layer; forming a gate stack within the opening; removing the hard mask layer; forming a spacer on a sidewall of the gate stack; and forming a second doped region in the substrate and under the spacer. The second doped region has a dopant concentration is larger than that of the first doped region. Therefore, the channel length in the substrate is increased and the leakage between the source region and the drain region can be improved.

In another embodiment, the present invention provides a semiconductor structure including a substrate, a partial surface of the substrate having a curve surface; an dielectric layer formed on the curve surface; a first doped region formed in the substrate; a gate stack formed on the dielectric layer; a spacer formed on a sidewall of the gate stack; and a second doped region formed in the substrate and under the spacer. Thus, the current leakage in the second doped region can be improved by increasing the surface distance of the substrate.

### BRIEF DESCRIPTION OF THE DRAWINGS

FIG. 1 to FIG. 6 respectively illustrate a cross-sectional view of forming a semiconductor structure in accordance with one embodiment of the present invention.

### DETAILED DESCRIPTION OF THE INVENTION

The preferred embodiments of the present invention will now be described in detail below. However, the present invention can be applied widely in other embodiments without departing from the spirit and scope of the invention, thus, the protected scope of the present invention is as set forth in the appended claims.

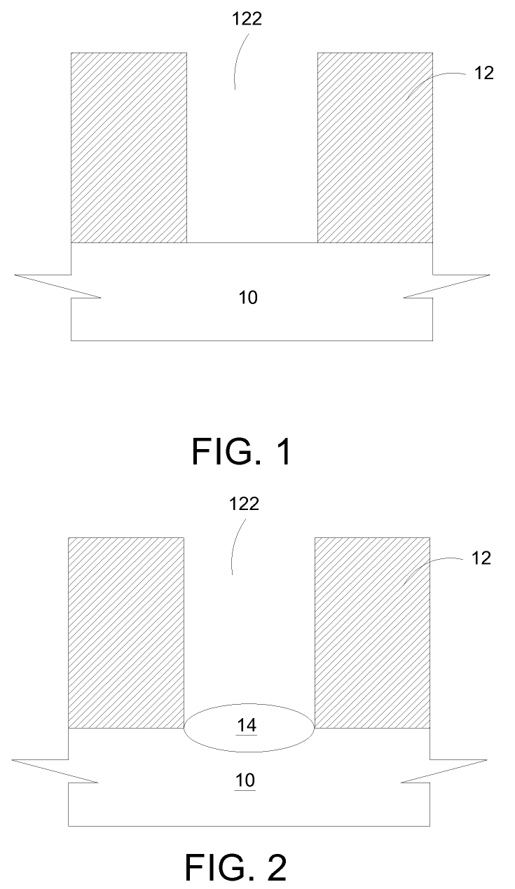

FIG. 1 to FIG. 6 illustrate cross-sectional views of a semiconductor structure and the process flow of a method for forming the same in accordance with the preferred embodiment of the present invention. As shown in FIG. 1, the method starts from providing a substrate 10 with a hard mask layer 12 formed thereon. Then, the hard mask layer 12 is patterned with an opening 122 by using any well-known patterning techniques, such as lithography, etching, etc., so as to expose a surface of the substrate 10. In one embodiment, the substrate 10 may be a silicon substrate, such as a silicon wafer, and the hard mask layer 12 may be an oxide layer, a nitride layer, or a combination thereof.

Referring to FIG. 2, an oxide layer 14 is formed on the substrate 10 within the opening 122. For example, the local oxidation of silicon (LOCOS) process is utilized to form the oxide layer 14 on the substrate 10 within the opening 122. The process of forming the oxide layer 14 is similar to the oxidation process implemented to form an isolation structure between metal-oxide semiconductor elements. That is, a portion of the substrate 10 is oxidized to form the oxide layer 14 by the thermal oxidation process. Therefore, the oxide layer 14 extended in the substrate 10 has a curve shape, which increases the exposed surface area of the substrate 10, and accordingly, increases a channel length in the substrate 10. As the channel length is longer, the leakage current is then reduced.

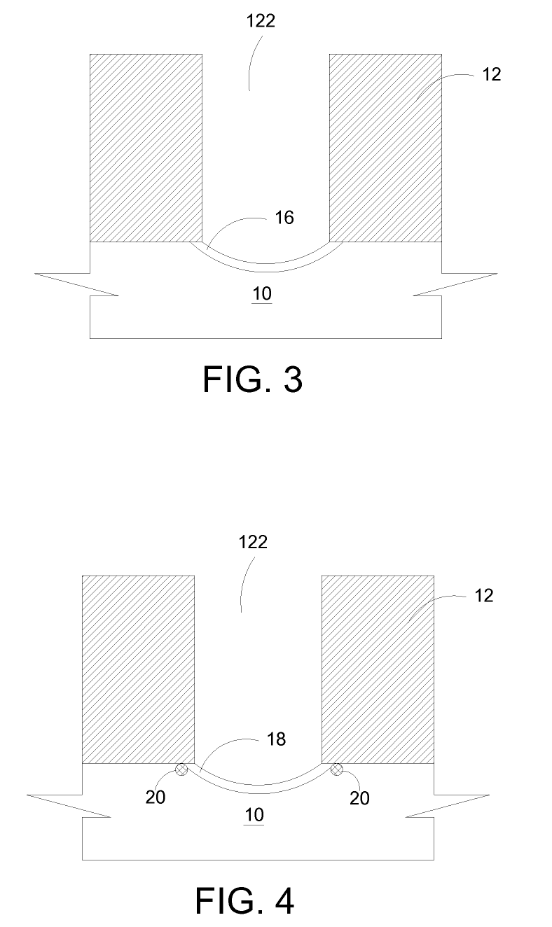

Referring now to FIG. 3, the oxide layer 14 is removed by a conventional technique, such as wet etching or dry etching process, to expose a partial surface of the substrate 10 within the opening 122. Due to the curve shape of the oxide layer 14, the exposed surface of the substrate 10 becomes a curve surface, such as a concave surface. Subsequently, a sacrificial layer 16 is formed on the curve surface of the substrate 10. In an exemplary embodiment, the sacrificial layer 16 can be an oxide layer formed by the thermal oxidation or the deposition process. In this embodiment, the sacrificial layer 16 is formed by the thermal oxidation process and the thickness thereof is about 80 nm.

Referring to FIG. 4, an angled ion implantation is performed on the structure of the FIG. 3 by using the hard mask layer 12 as a protection mask to form a first doped region 20 in the substrate 10 and under the hard mask layer 12. In this embodiment, the first doped region 20 may be a lightly-doped drain region (LDD region). For example, the angled ion implantation is preferably performed with an implant angle of about 5 to 10 degree, so as to reduce the drift speed of the arsenic ions in the gate dielectric layer to be formed. Furthermore, by using such a shallow angled ion implantation, the lightly-doped drain region masked by the hard mask layer 12 can be reduced. It should be noted that the type of the dopants can be P-type ion or N-type ion according to the type of the metal-oxide semiconductor field-effect transistor to be formed.

Then, the sacrificial layer 16 is removed, for example, by using wet etching. A dielectric layer 18 is then formed on the curve surface of the substrate 10 to serve as a gate dielectric layer. The dielectric layer 18 can be formed by, for example, thermal oxidation.

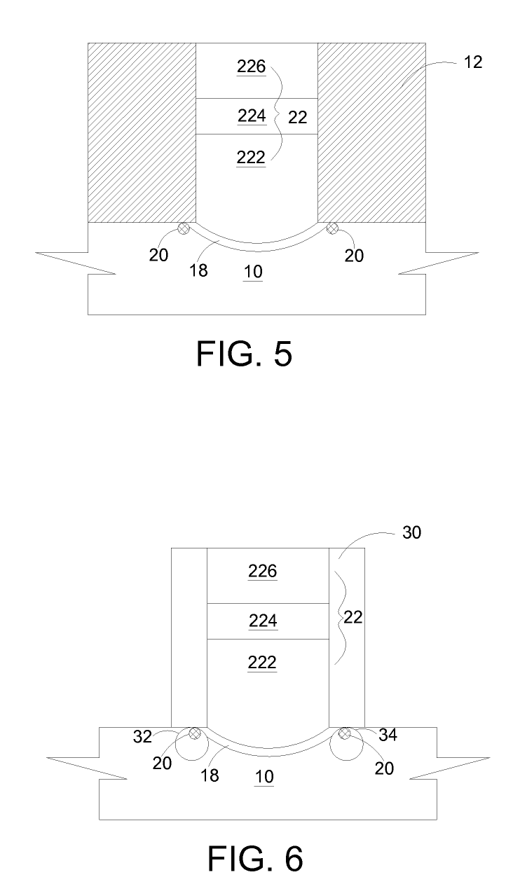

Referring to FIG. 5, a conductive layer, such as a polysilicon layer 222, is formed on the dielectric layer 18 within the opening 122 to serve as a control gate of a MOS transistor. The polysilicon layer 222 can be first formed to cover the hard mask layer 12 and the dielectric layer 18 by a deposition process, selectively planarized, and then etched back so that the polysilicon layer 222 is formed on the substrate 10 within the opening 122, as shown in FIG. 5. Subsequently, a metal layer 224 is formed to cover the hard mask layer 12 and the polysilicon layer 222. Similarly, by using the well-known deposition, polishing and etching back technologies, the metal layer 224 is recessed so that the metal layer 224 is formed on the polysilicon layer 222 within the opening 122, as shown in FIG. 5. In an exemplary embodiment, the metal layer 224 is a tungsten (W) layer. In other embodiments, the metal layer 224 can be a metal silicide layer, such as a tungsten silicide (WSi) layer.

Then, a cap layer 226 is formed on the metal layer 224 and the hard mask layer 12. Similarly, a portion of the cap layer 226 is removed by an etching process or a planarization process, such as chemical mechanical polishing, so that the cap layer 226 is on the metal layer 224 and co-plane with the hard mask layer 12. Consequently, the polysilicon layer 222, the metal layer 224, and the cap layer 226 constitute a gate stack 22. In an exemplary embodiment, the cap layer 226 can be an oxide layer, a nitride layer, or a combination thereof. In this embodiment, if the hard mask layer 12 is an oxide layer, the cap layer 226 can be a silicon nitride layer, and vise versa.

Furthermore, referring to FIG. 6, the hard mask layer 12 is removed and the gate stack 22 remains. Then, a spacer 30, such as an oxide layer, a nitride layer, or a combination thereof, is formed on a sidewall of the gate stack 22. Optionally, a liner layer (not shown) is formed on the gate stack 22. Subsequently, a second ion implantation is performed so as to form a second doped region, such as 32, 34, in the substrate 10 and under the spacer 30. In this embodiment, the second doped regions 32, 34 has a dopant concentration larger than that of the first doped region 20 to serve as source/drain regions.

Therefore, the present invention implements the thermal oxidation to form an oxide layer on the substrate so as to increase the surface area (or length) of the substrate. Thus, the distance between the source region and the drain region is increased, and accordingly, the channel length is increased, so that the leakage between the source region and the drain region can be improved.

Furthermore, different from the conventional MOS manufacturing process, the first doped region (lightly-doped drain region) of the present invention is formed in the substrate before the formation of the gate stack structure, and consequently, a more reliable MOS device can be achieved.

Although specific embodiments have been illustrated and described, it will be obvious to those skilled in the art that various modifications may be made without departing from what is intended to be limited solely by the appended claims.

What is claimed is:

1. A method of forming a semiconductor structure, comprising:
providing a substrate with a mask layer on top of said substrate and an opening defined in said mask layer to expose a portion of a top surface of said substrate;
recessing said exposed portion of said top surface of said substrate to allow said exposed portion of said top surface to become a concave surface;
forming a sacrificial layer on said concave surface;
forming a first doped region in said substrate and under said mask layer;
forming a gate stack within said opening and on top of said concave surface;
removing said mask layer;
forming a spacer on a sidewall of said gate stack; and
forming a second doped region in said substrate and under said spacer.

2. The method of forming a semiconductor structure of claim 1, after forming said first doped region, further comprises:
removing said sacrificial layer; and
forming a gate dielectric layer on said concave surface of said substrate, so that said gate stack is formed on said gate dielectric layer.

3. The method of forming a semiconductor structure of claim 2, wherein said second doped region has a dopant concentration larger than that of said first doped region.

4. The method of forming a semiconductor structure of claim 1, wherein said mask layer comprises an oxide layer, a nitride layer or a combination thereof.

5. The method of forming a semiconductor structure of claim 1, wherein said gate stack comprises a polysilicon layer, a metal layer, and a cap layer.

6. The method of forming a semiconductor structure of claim 1, wherein said gate stack comprises a polysilicon layer, a metal silicide layer and a cap layer.

7. The method of forming a semiconductor structure of claim 1, wherein said spacer comprises an oxide layer, a nitride layer, or a combination thereof.

8. A semiconductor structure made by the method as claimed in claim 1, the semiconductor structure comprising:
a substrate, a partial surface of said substrate having a concave surface;
a dielectric layer formed on said concave surface;
a first doped region formed in said substrate;
a gate stack formed on said dielectric layer;
a spacer formed on a sidewall of said gate stack; and
a second doped region formed in said substrate and under said spacer.

9. The semiconductor structure of claim 8, wherein said second doped region has a dopant concentration larger than that of said first doped region, said gate stack comprises a polysilicon layer, a metal layer, and a cap layer, said gate stack comprises a polysilicon layer, a metal silicide layer, and a cap layer, and said spacer is an oxide layer, a nitride layer, or a combination thereof.
